(19) United States
(12) Patent Application Publication
(10) Pub. No.: US 2020/0358249 A1
(43) Pub. Date: Nov. 12, 2020

(54) SEMICONDUCTOR PACKAGE AND LIDAR TRANSMISSION UNIT

(71) Applicant: Ibeo Automotive Systems GmbH, Hamburg (DE)

(72) Inventor: Stefan Hakspiel, Meckenbeuren (DE)

(73) Assignee: Ibeo Automotive Systems GmbH, Hamburg (DE)

(21) Appl. No.: 16/867,917

(22) Filed: May 6, 2020

(30) Foreign Application Priority Data
May 7, 2019 (DE) 102019206508.2

(51) Int. Cl. H01S 5/183; H01L 23/00; G01S 7/484; H01L 23/488

(52) U.S. Cl. CPC H01S 5/183; H01L 23/488; G01S 7/484; H01L 24/14

(57) ABSTRACT

The present invention relates to a semiconductor package and to a LIDAR transmitting unit including such a semiconductor package. The semiconductor package has a surface-emitting laser, at least one driver circuit for the surface-emitting laser, a connecting structure and at least one interposer. The connecting structure includes a plurality of solder bumps. The surface-emitting laser is electrically connected to the at least one driver circuit via the at least one interposer and the connecting structure.

### FIELD OF THE INVENTION

The present invention relates to a semiconductor package, more precisely to a semiconductor package comprising a surface-emitting laser, at least one driver circuit for the surface-emitting laser and at least one interposer as well as to a LIDAR transmitting unit comprising such a semiconductor package.

### BACKGROUND OF INVENTION

In laser array arrangements, such as for LIDAR applications (Light Detection and Ranging, light-based detection and distance measurement), surface-emitting lasers, so-called VCSEL (Vertical-Cavity Surface-Emitting Laser, surface-emitting laser with a vertical resonator) are frequently used. These surface-emitting lasers, together with corresponding driver circuits, are arranged on a semiconductor package. In this case, it is usual that the electrical contacting between the driver circuits and the surface-emitting laser is made by means of bond wires.

In some applications such as in the automobile area, such bond wires have a distance, also called “pitch”, which is limited by a minimum distance in order to eliminate contacts which can result in short circuits. As a result, the arrays of the laser diodes in the surface-emitting laser have a minimum distance which is based on the minimum distance of the bond wires. In the case of an at least required resolution of the surface-emitting laser, a minimum size of the laser is thus predefined which can result in high costs in the semiconductor fabrication since both the semiconductor surface per se and also the error rate, which increases the rejects in the case of larger semiconductor components results in higher costs.

The object according to the invention is therefore to provide a more inexpensive laser array which can be used in the automobile area, such as in LIDAR applications.

### SUMMARY OF THE INVENTION

The invention is based on the idea of using, instead of contacting by bond wires, contacting via a so-called interposer, wherein the interposer makes contact with the surface-emitting laser and the corresponding driver circuits via so-called solder bumps. Since such interposers can also be fabricated in a semiconductor fabrication process, these can have a very small pitch of the contacts which makes it possible to use surface-emitting lasers with a narrow array spacing. As a result, whilst the resolution of the surface-emitting laser remains the same, the laser can be reduced in size so that inexpensive laser arrays are possible.

Exemplary embodiments thus create a semiconductor package comprising a surface-emitting laser, at least one driver circuit for the surface-emitting laser, a connecting structure and at least one interposer. The connecting structure comprises a plurality of solder bumps. The surface-emitting laser is electrically connected to the at least one driver circuit via the at least one interposer and the connecting structure. As has already been stated above, the object according to the invention is achieved by such a semiconductor package.

In some variants, the semiconductor package further comprises a potting structure. This potting structure can be designed to shield the connecting structure with respect to external effects. This makes it possible to achieve a greater robustness of the semiconductor package, specifically in the raw automobile area.

In this case, the potting structure can be arranged at least partially between the surface-emitting laser and a package substrate of the semiconductor package Thus, the potting structure can be part of the so-called underfill of the semiconductor package.

Nevertheless, a part of the surface-emitting laser can be in direct contact with the package substrate. This allows a stable fastening of the surface-emitting laser to the package substrate.

The at least one interposer can, for example, be arranged at least partially vertically between the surface-emitting laser and the package substrate. Alternatively, the at least one interposer can be formed by the package substrate. This enables a flat construction.

Alternatively the at least one surface-emitting laser can be arranged at least partially vertically between the at least one interposer and the package substrate. This optionally enables a more stable fastening of the surface-emitting laser and the at least one driver circuit on the package substrate.

In exemplary embodiments, the plurality of solder bumps corresponds to a plurality of micro-bumps. This makes it possible to achieve a particularly narrow pitch.

In at least some exemplary embodiments, the semiconductor package comprises a further connecting structure. A connection structure of the package substrate can be electrically connected to the at least one driver circuit via the further connecting structure. This enables electrical contacting of the at least one driver circuit via the package substrate.

Accordingly, the semiconductor package can also comprise a further potting structure. The further potting structure can be designed to shield the further connecting structure with respect to external effects. This enables a greater robustness of the semiconductor package, specifically in the harsh automobile environment.

In this case, the at least one driver circuit can be electrically connected to the connection structure of the package substrate via various contacting technologies. Thus, the at least one driver circuit can be electrically connected to the connection structure of the package substrate via one or more bond wires of the further connecting structure in each case. Alternatively or additionally the at least one driver circuit can be electrically connected to the connection structure of the package substrate via one or more solder bumps of the further connecting structure in each case. Both contacting technologies have advantages and disadvantages in relation to fabrication, costs and robustness.

The at least one driver circuit can, for example, be electrically connected to the connection structure of the package substrate via one or more solder bumps of the further connecting structure in each case via the at least one interposer. Thus, the interposer can serve as a support on which the remaining components are arranged.

In at least some exemplary embodiments, the at least one interposer is at least one semiconductor component. This makes it possible to fabricate particularly fine structures and therefore also a particularly small pitch.

A horizontal surface of the at least one interposer can project at least partially laterally beyond a horizontal surface of the surface-emitting laser and the at least one driver circuit. This enables a contacting of the interposer via bond wires, e.g. in order to electrically contact the interposer with the package substrate.

Exemplary embodiments thus create a robust and/or miniaturized structure of electronic components for laser array and lidar applications. In this case, by using new micro-electronic structure and connection techniques, such as the use of bumps, a further miniaturization of the laser diode distances can be achieved. Since the special semiconductor materials are extremely expensive, by this means chip area and therefore costs can be saved. In addition, such a connection is more robust than that made by bond wires.

### BRIEF DESCRIPTION OF THE DRAWINGS

Further advantageous configurations are described in detail hereinafter with reference to the exemplary embodiments shown in the drawings, to which exemplary embodiments however the invention is not generally restricted overall.

FIG. 1 shows an exemplary embodiment of a semiconductor package;

FIG. 2 shows a further exemplary embodiment of a semiconductor package which comprises at least one potting structure;

FIG. 3 shows a further exemplary embodiment of a semiconductor package in which two interposers are arranged between the package substrate and the surface-emitting laser;

FIG. 4 shows a further exemplary embodiment of a semiconductor package in which a part of the surface-emitting laser is in direct contact with the package substrate; and

FIG. 5 shows a further exemplary embodiment of a semiconductor package in which the surface-emitting laser and two driver circuits are arranged on the interposer.

### DETAILED DESCRIPTION OF THE PREFERRED EMBODIMENTS

Exemplary embodiments are now described in detail with reference to the appended drawings which show some exemplary embodiments. In the following description of the appended figures which merely show some exemplary embodiments, the same reference numbers can designate the same or comparable components. Furthermore, summarizing reference numbers can be used for components and objects which occur multiple times in one exemplary embodiment or in one drawing but are described jointly with regard to one or several features. In this case, a vertical extension or a vertical arrangement is defined orthogonally to a front side of the package substrate and a lateral extension or a lateral arrangement is defined parallel to the front side of the package substrate.

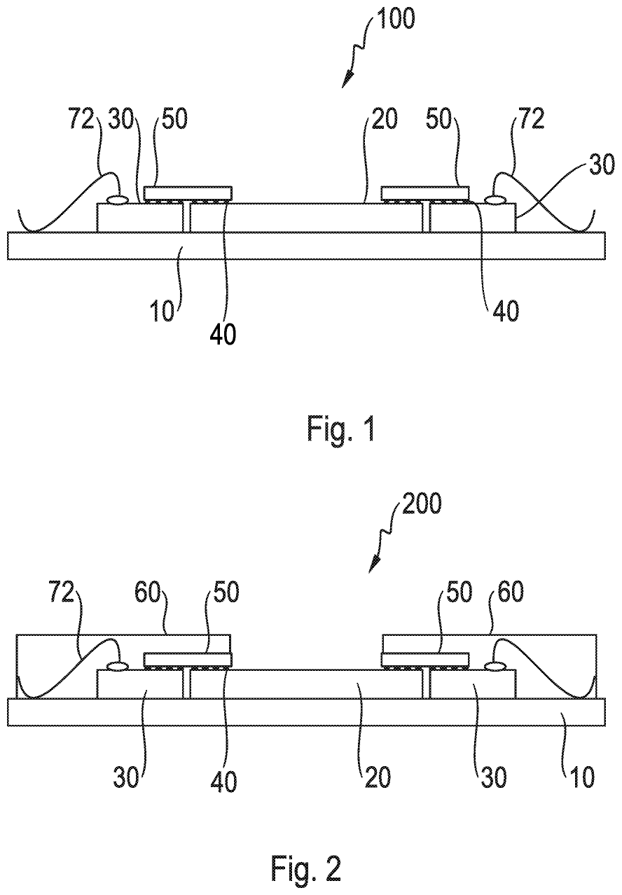

FIG. 1 shows an exemplary embodiment of a semiconductor package. The semiconductor package 100 comprises a package substrate 10, a surface-emitting laser 20, two driver circuits 30 for the surface-emitting laser 20, a connecting structure 40 and two interposers 50. The connecting structure comprises a plurality of solder bumps. The surface-emitting laser is electrically connected to the at least one driver circuit via the at least one interposer and the connecting structure.

The semiconductor package shown in FIG. 1 constitutes an exemplary embodiment of semiconductor packages according to the invention. Semiconductor package means in this case that the semiconductor package is provided to accommodate at least one semiconductor chip, such as the surface-emitting laser and the at least one driver circuit and to provide a contacting structure for connecting the at least one semiconductor chip. In this case, the individual components of the semiconductor package, in particular the package substrate, need not be fabricated from semiconductor materials. In the exemplary embodiments the package substrate can be any package substrate, e.g. one made of printed circuit board material. In this case, the package substrate can be an (organic) plastic substrate or a ceramic substrate. In some exemplary embodiments, no conductor tracks run through or on the package substrate. Thus, the package substrate can also be an aluminium package substrate.

The semiconductor package can in this case be a multi-chip module, i.e. it can accommodate more than only one chip, such as the surface-emitting laser and the at least one driver circuit. In this case, in the semiconductor package of FIG. 1 two driver circuits 30 and the surface-emitting laser 20 are arranged directly on the package substrate or they are in direct contact with the semiconductor substrate. In this context, “arranged directly on” or “is in direct contact” merely means that a fastening means such as a solder fastening or a fastening adhesive is arranged between the package substrate and the respective component (driver circuit, surface-emitting laser or subsequently also interposer). In particular, a potting structure, a so-called potting, is not arranged between the package substrate and the respective component.

In the exemplary embodiment of FIG. 1 (and also in the exemplary embodiment of FIG. 2), each interposer is arranged vertically above the surface-emitting laser and one of the two driver circuits. In other words, the at least one surface-emitting laser 20, as well as the two driver circuits, is arranged at least partially vertically between the interposer 50 and the package substrate 10.

In the exemplary embodiments of FIGS. 1 to 5, the plurality of solder bumps are formed by micro-bumps. Micro bumps constitute a special form of solder bumps and defined by the fact that they are smaller than “normal” solder bumps. Micro-bumps can have a diameter of less than 50 μm (or less than 30 μm). Micro-bumps having significantly smaller diameters are also known down to 1 μm. Micro-bumps make it possible to achieve a particularly small spacing between adjacent solder bumps and as a result a particularly small array spacing of the surface-emitting laser. In this case, a spacing between adjacent solder bumps of the plurality of solder bumps can be less than 100 μm, such as less than 80 μm or less than 50 μm. In this case, adjacent implies that the two solder bumps whose spacing is measured are arranged on the same component (laser or driver circuit). As an alternative to micro-bumps, so-called copper pillars can also be used. In the present application, these are also counted as solder bumps.

In order to be able to bring the interposer and the surface-emitting laser or the two driver circuits electrically in contact with one another, so-called re-flow techniques can be used in which the material of the bumps is partially liquefied before the interposer is placed on the laser and a driver circuit (or conversely if the interposer or interposers are arranged between package substrate and laser/driver circuit) and the interposer with the partially liquefied bumps is placed on corresponding contacts of the surface-emitting laser and a driver circuit. In this case, the partially liquefied bumps form a self-aligning structure when solidifying so that the interposer is aligned in a precisely fitting manner to the contacts of the surface-emitting laser and the respective driver circuit. The liquefying can be brought about, for example, by hot air.

In at least some of the exemplary embodiments, the interposer is a semiconductor component, i.e. the interposer can be fabricated from a semiconductor material such as silicon, silicon carbide or gallium arsenide. In other words the interposer can be fabricated from or on a semiconductor wafer. Alternatively the interposer itself can comprise a package substrate which allows fine granular conductor tracks and contacts, i.e. the interposer can be formed by a further package substrate. In this case, the interposer can comprise a first plurality of contacts for the contacting of the surface-emitting laser, a second plurality of contacts for the contacting of a driver circuit and a plurality of conductor tracks which produce an electrical connection between the first plurality of contacts and the second plurality of contacts. In this case, the first plurality of contacts and the second plurality of contacts can be arranged on the same side of the interposer.

In at least some exemplary embodiment, the surface-emitting laser is a VCSEL array, i.e. the surface-emitting laser comprises a plurality of emitter elements in a first lateral extension of the surface-emitting laser and a plurality of emitter elements in a second lateral extension of the surface-emitting laser arranged orthogonally to the first. For example, the surface-emitting laser can comprise a plurality of emitter elements which are arranged in a matrix arrangement. Alternatively a different arrangement can be selected, such as an arrangement based on hexagons.

In his case, the plurality of laser emitters can be controlled line-by-line, i.e. each driver circuit can comprise a plurality of driver cells, wherein each cell is configured to control one line of the surface-emitting laser. Each line of the surface-emitting laser can in turn comprise a plurality of emitter elements. In this case, as shown in FIGS. 1 to 5, if a plurality of driver circuits is used, the control of the lines can be accomplished in an “interleaved” manner. This means that in the case of two driver circuits, the lines of the surface-emitting laser can be controlled line-by-line alternately by the two driver circuits. This in turn makes it possible to achieve a smaller line spacing.

For example, the surface-emitting laser can be a surface-emitting laser for a LIDAR transmitting unit. This LIDAR transmitting unit can correspond to the semiconductor package or the LIDAR transmitting unit can comprise the semiconductor package. The surface-emitting laser can be configured to produce a plurality of laser beams through the plurality of emitter elements which are provided to be transmitted via a transmission optics, in this case, preferably laser pulses are used.

The at least one driver circuit is configured to control at least a part of the surface-emitting laser. In this case, the at least one driver circuit can be configured to generate a plurality of power supply signals based on a control signal in order to control the plurality of emitter elements. In other words, each driver circuit can be configured to control the power supply of a plurality of emitter elements of the surface-emitting laser (based on the control signal). In this case, each driver circuit can be configured to receive the control signal via a further connecting structure. The semiconductor package can comprise the further connecting structure. A connection structure of the package substrate 10 can be electrically connected to the at least one driver circuit 30 via the further connecting structure. The control signal can be transmitted via the further connecting structure. In this case, the further connecting structure is formed as bond wires 72 in FIGS. 1 and 2. In other words, the at least one driver circuit 30 can in each case be electrically connected to the connection structure of the package substrate 10 via one or more bond wires 72 of the further connecting structure. In this case, the connection structure of the package substrate can, for example, comprise a first plurality of contacts (contact pads) for connection of the semiconductor package to a further component and a second plurality of contacts for connection of the driver circuit/driver circuits to the connection structure. Alternatively the same contact pads can be used for connection of the semiconductor package to a further component and for connection of the driver circuit/driver circuits to the connection structure. In at least some exemplary embodiments, the connection structure further comprises a plurality of conductor tracks in order to electrically connect the first plurality of contacts to the second plurality of contacts.

As has already been described above, the semiconductor package can be part of a LIDAR transmitting unit or correspond to a LIDAR transmitting unit. A LIDAR transmitting unit is usually a component of a LIDAR measuring system. Exemplary embodiments thus also create a LIDAR measuring system comprising a LIDAR transmitting unit with the semiconductor package and a LIDAR receiving unit. The LIDAR measuring system is configured in its basic structure according to the explanations for the prior art (WO 2017/081294 A1).

The LIDAR receiving unit and/or the LIDAR transmitting unit are favourably configured in a focal plane array configuration. The elements of the respective unit are substantially arranged in one plane, favourably on a chip. The respective unit is preferably arranged on the LIDAR measuring system at a focal point of a corresponding optics, transmission optics or receiving optics. In particular, the sensor elements or the emitter elements are arranged at the focal point of the receiving optics. Such optics can, for example, be formed by an optical lens system.

The LIDAR receiving unit comprises a plurality of sensor elements which are preferably formed as SPADs, single photon avalanche diodes. The LIDAR transmitting unit comprises a plurality of emitter elements for emitting laser lights, favourably laser pulses. The emitter elements are favourably configured as VCSEL, vertical cavity surface emitting laser.

The transmitting unit comprises emitter elements which are distributed over the surface of the transmitting chip, of the surface-emitting laser. The receiving unit comprises sensor elements which are distributed over a surface of the receiving chip. Transmission optics are assigned to the transmitting chip and receiving optics are assigned to the receiving chip. The optics image light from a spatial region on the respective chip. The spatial region corresponds to the viewing range of the measurement system which is investigated or sensed on objects. The spatial region of the transmitting unit and the receiving unit are substantially identical. The transmission optics image an emitter element onto a solid angle which forms a partial region of the spatial region. The emitter element accordingly emits laser light in this solid angle. The emitter elements together cover the entire spatial region.

The receiving optics image a sensor element onto a solid angle which forms a partial region of the spatial region. The number of all the sensor elements covers the entire spatial region. Emitter elements and sensor elements which observe the same solid angle image onto one another and are accordingly assigned to one another. Laser light of an emitter element always images onto the relevant sensor element in the normal case. Optionally a plurality of sensor elements are arranged within the solid angle of an emitter element.

In order to determine objects within the spatial region, the measurement system performs a measurement process. Such a measurement process comprises one or more measurement cycles according to the constructive structure of the measurement system and its electronics.

Preferably the time correlated single photon counting method, TCSPC is used. In this case, individual incident photons are detected, in particular by SPAD and the time of triggering of the sensor element, also detection time, is stored in a storage element. The detection time is related to a reference time at which the laser light is emitted. The transit time of the laser light can be determined from the difference, from which the distance of the object can be determined.

A sensor element can be triggered on the one hand by the laser light and on the other hand by the ambient radiation. Laser light is always incident at the same time in the case of a specific distance of the object whereas the ambient light provides the same probability to trigger a sensor element at any time. When a measurement is carried out multiple times, in particular a plurality of measurement cycles, the triggerings of the sensor element are summed at the detection time which corresponds to the transit time of the laser light in relation to the distance of the object, whereas the triggerings by the ambient radiation are distributed uniformly over the measurement time of a measurement cycle. A measurement corresponds to the emission and subsequent detection of the laser light. The data of the individual measurement cycles of a measurement process stored in the storage element make it possible to evaluate the multiply determined detection times in order to determine the distance of the object.

A sensor element is favourably connected to a time to digital converter, TDC which stores the time of the triggering of the sensor unit in the storage element. Such a storage element can be configured, for example, as a short-term storage device or as a long-term storage device. The TDC fills a storage unit for a measurement process with the times at which the sensor elements detected an incident photon. This can be represented graphically by a histogram which is based on the data of the storage element. In a histogram the duration of a measurement cycle is divided into short time periods, so-called bins. If a sensor element is triggered, the TDC increases the value of a bin by one. The bin which corresponds to the transit time of the laser pulse, i.e. the difference between detection time and reference time, is filled.

FIG. 2 shows a further exemplary embodiment of a semiconductor package which comprises at least one potting structure 60. The semiconductor package 200 comprises a package substrate 10, a surface-emitting laser 20, two driver circuits 30 for the surface-emitting laser 20, a connecting structure 40 and two interposers 50. The connecting structure comprises a plurality of solder bumps. The surface-emitting laser is electrically connected to the at least one driver circuit via the at least one interposer and the connecting structure. In many respects the semiconductor package 200 thus has a similar structure to the semiconductor package of FIG. 1.

In addition to the semiconductor package of FIG. 1, the semiconductor package 200 further comprises the potting structure 60. The potting structure is designed from a potting material, such as from a synthetic resin. In this case, for example, thermoplastic or thermosetting plastics can be used. The potting structure 60 is designed to shield the connecting structure 40 with respect to external effects. Thus, the potting structure 60 can completely enclose the connecting structure 40, i.e. the plurality of solder bumps, at least at those points where the plurality of solder bumps are not in contact with contacts of the interposer, the at least one driver structure of the surface-emitting laser. In the semiconductor package of FIG. 2, the potting structure 60 encloses the at least one driver circuit 30 and the connecting structure 40 as well as the surface-emitting laser and the interposer at least partially. Here care should be taken to ensure that the surface-emitting laser is not covered by the potting structure in an emission direction of the surface-emitting laser (unless a transparent material is used for the potting structure).

As is further shown in FIG. 2, the potting structure 60 can be further designed to shield the further connecting structure (with the bond wires 72) with respect to external effects. In other words, the potting structure 60 can at least completely enclose the further connecting structure 40, i.e. the bond wires 72, at least where the further connecting structure 40 is not in contact with the connection structure of the package substrate or with contacts of the at least one driver circuit.

More details and aspects of the semiconductor package 200 are mentioned in connection with the concept or examples which were described previously (e.g. FIG. 1). The semiconductor package 200 can comprise one or more additional optional features which correspond to one or more aspects of the proposed concept or the described examples such as have been described previously or subsequently.

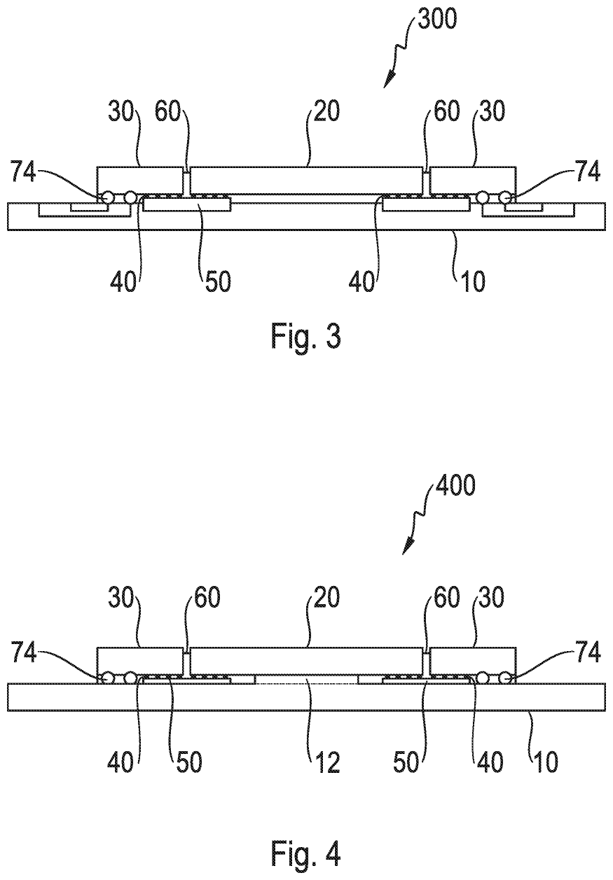

FIG. 3 shows a further exemplary embodiment of a semiconductor package in which two interposers 50 are arranged between a package substrate 10 and a surface-emitting laser 20. The semiconductor package 300 comprises the package substrate 10, the surface-emitting laser 20, two driver circuits 30 for the surface-emitting laser 20, a connecting structure 40 and the two interposers 50. The connecting structure comprises a plurality of solder bumps. The surface-emitting laser is electrically connected to the at least one driver circuit via the two interposers and the connecting structure. In many respects the semiconductor package 300 thus has a similar structure to the semiconductor packages of FIG. 1 and/or FIG. 2.

In contrast to the exemplary embodiments of FIGS. 1 and 2, in the exemplary embodiment of FIG. 3, the two interposers 50 are arranged vertically at least partially between the surface-emitting laser 20 and the package substrate 10. Furthermore, the two interposers 50 are arranged vertically at least partially between one of the interposers and the package substrate. In a further feasible embodiment the interposer or interposers 50 can be integrated in the package substrate 10, i.e. formed by the package substrate 10, if the package substrate is fabricated from a printed circuit board material or from semiconductor material.

Accordingly, the potting structure 60 is also arranged at least partially between the surface-emitting laser 20 and the package substrate 10 and at least partially between the two driver circuits and the package substrate. In this case, the potting structure can be used as so-called underfill. The potting structure can be further configured to shield the further connecting structure, here formed by solder bumps 74 with respect to external effects. As can be further seen in FIG. 3, the potting structure is furthermore arranged at least partially laterally between the surface-emitting laser and the two driver circuits.

As has already been described above, the semiconductor package 300 further comprises the further connecting structure. A connection structure of the package substrate 10 (contact pads, not shown) is electrically connected to the at least one driver circuit 30 via the further connecting structure. In this case, the further connecting structure comprises one or more solder bumps or solder balls 74 which are arranged between the driver circuits and the package substrate. In other words, the at least one driver circuit 30 is electrically connected to the connection structure of the package substrate 10 in each case via one or more solder bumps 74 or solder balls of the further connecting structure. In addition, the further connecting structure comprises conductor tracks which electrically connect the solder bumps 74 to the contacts of the package substrate (not shown) which are suitable for connection of the semiconductor package.

More details and aspects of the semiconductor package 300 are mentioned in connection with the concept or examples which were described previously (e.g. FIG. 1). The semiconductor package 300 can comprise one or more additional optional features which correspond to one or more aspects of the proposed concept or the described examples such as have been described previously or subsequently.

FIG. 4 shows a further exemplary embodiment of a semiconductor package 400 in which a part of the surface-emitting laser 20 is in direct contact with the package substrate 10. The semiconductor package 400 comprises the package substrate 10, the surface-emitting laser 20, two driver circuits 30 for the surface-emitting laser 20, a connecting structure 40 and the two interposers 50. The connecting structure comprises a plurality of solder bumps. The surface-emitting laser is electrically connected to the at least one driver circuit via the two interposers and the connecting structure. In many respects, the semiconductor package 400 thus has a similar structure to one of the semiconductor packages of FIG. 1 to FIG. 3, in particular is similar to the semiconductor package from FIG. 3.

As also in FIG. 3, the at least one interposer 50 is arranged at least partially vertically between the surface-emitting laser 20 and the package substrate 10 and a potting structure 60 is arranged at least partially between the surface-emitting laser 20 and the package substrate 10. In contrast to FIG. 3, at least a part of the surface-emitting laser 20 is in direct contact with the package substrate 10. The package substrate can in this case be a support or submount with x-y stabilizer. For this purpose the package substrate can have a stabilizing section 12 which is in direct contact with the surface-emitting laser 20. This stabilizing section is an elevated section with respect to the remaining surface of the package substrate which is provided to be in direct contact with the surface-emitting laser. In this case, the stabilizing section can be designed to stabilize the surface-emitting laser laterally, i.e. to prevent any movement of the surface-emitting laser in the lateral plane.

More details and aspects of the semiconductor package 400 are mentioned in connection with the concept or examples which were described previously (e.g. FIGS. 1 to 3). The semiconductor package 400 can comprise one or more additional optional features which correspond to one or more aspects of the proposed concept or the described examples such as have been described previously or subsequently.

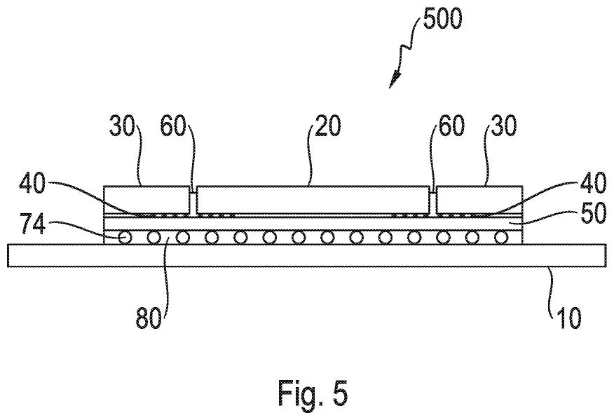

FIG. 5 shows a further exemplary embodiment of a semiconductor package 500 in which the surface-emitting laser 20 and two driver circuits 30 are arranged on an interposer 50. The semiconductor package 500 comprises the package substrate 10, the surface-emitting laser 20, two driver circuits 30 for the surface-emitting laser 20, a connecting structure 40 and a (single) interposer 50. The connecting structure comprises a plurality of solder bumps. The surface-emitting laser is electrically connected to the at least one driver circuit via the interposer and the connecting structure. In many respects the semiconductor package 400 thus has a similar structure to a semiconductor package from FIG. 1 to FIG. 4.

In the case of the semiconductor package 500, the interposer 50 is also arranged vertically between the surface-emitting laser 20 and the package substrate 10. In this case, the interposer even forms a platform for the surface-emitting laser 20 and the two driver circuits 30, i.e. in this case the combination of interposer, laser, driver circuits and connecting structure can be mounted as a cohesive unit on the package substrate 40. For this purpose the interposer 50 can be coupled non-positively to the surface-emitting laser 20 and the driver circuits 30 via the connecting structure 40. In this case, the interposer 50 and the package substrate 10 are two separate components. Alternatively the at least one interposer 50 can be formed by the package substrate 50 or rather the interposer 50 can form the package substrate. In this case, the package substrate which also forms the interposer 50 can be a semiconductor component. As in other exemplary embodiments, the potting structure 60 is arranged at least partially between the surface-emitting laser 20 and/or the driver circuits 30 and the package substrate 10.

As shown in FIG. 5, the semiconductor package 500 can comprise a further connecting structure. A connection structure of the package substrate 10 can be electrically connected to the at least one driver circuit 30 via the further connecting structure. This can be accomplished, as shown in FIG. 5, by solder bumps or solder balls. In other words 11, the at least one driver circuit 30 can in each case be electrically connected to the connection structure of the package substrate 10 via one or more solder bumps 74 of the further connecting structure. In this case, the at least one driver circuit 30 can in each case be electrically connected to the connection structure of the package substrate via one or more solder bumps 74 of the further connecting structure via the at least one interposer 50. Alternatively bond wires can be used. In other words, the at least one driver circuit 30 can be electrically connected to the connection structure of the package substrate 10 via one or more bond wires of the further connecting structure. In this case, the one or more bond wires 72 can be connected to the connection structure of the package substrate 10 and to contacts of the driver circuits, similar to that in FIGS. 1 and 2. Alternatively the one or more bond wires can be connected to the connection structure of the package substrate 10 and to contacts of the interposer 50 (not shown). For this purpose a horizontal surface of the at least one interposer 50 can project laterally at least partially beyond a horizontal surface of the surface-emitting laser and the at least one driver circuit so that an edge is created at which the one or more bond wires can be fastened to contacts of the interposer 50. In this case, the further connecting structure can comprise one or more solder bumps 74 (for the electrical connection between driver circuit and interposer) and also one or more bond wires (for the electrical connection between interposer and connection structure of the package substrate). In this case, the further connecting structure can in turn be shielded by a further potting structure 80.

More details and aspects of the semiconductor package 500 are mentioned in connection with the concept or examples which were described previously (e.g. FIGS. 1 to 4). The semiconductor package 500 can comprise one or more additional optional features which correspond to one or more aspects of the proposed concept or the described examples such as have been described previously or subsequently.

1. Semiconductor package comprising:
a surface-emitting laser;
at least one driver circuit for the surface-emitting laser;
a connecting structure, wherein the connecting structure comprises a plurality of solder bumps; and
at least one interposer, wherein the surface-emitting laser is electrically connected to the at least one driver circuit via the at least one interposer and the connecting structure.

2. Semiconductor package according to claim 1, further comprising a potting structure, wherein the potting structure is designed to shield the connecting structure with respect to external effects.

3. Semiconductor package according to claim 2, wherein the potting structure is arranged at least partially between the surface-emitting laser and a package substrate of the semiconductor package.

4. Semiconductor package according to claim 3, wherein at least a part of the surface-emitting laser is in direct contact with the package substrate.

5. Semiconductor package according to claim 1, wherein the at least one interposer is arranged at least partially vertically between the surface-emitting laser and a package substrate of the semiconductor package or wherein the at least one interposer is formed by the package substrate.

6. Semiconductor package according to claim 1, wherein the at least one surface-emitting laser is arranged at least partially vertically between the at least one interposer and a package substrate of the semiconductor package.

7. Semiconductor package according to claim 1, wherein the plurality of solder bumps corresponds to a plurality of micro-bumps.

8. Semiconductor package according to claim 1, comprising a further connecting structure, wherein one connection structure of a package substrate of the semiconductor package is electrically connected to the at least one driver circuit via the further connecting structure.

9. Semiconductor package according to claim 8, further comprising a further potting structure, wherein the further potting structure is designed to shield the further connecting structure with respect to external effects.

10. Semiconductor package according to claim 8, wherein the at least one driver circuit is electrically connected to the connection structure of the package substrate in each case via one or more bond wires of the further connecting structure.

11. Semiconductor package according to claim 8, wherein the at least one driver circuit is electrically connected to the connection structure of the package substrate in each case via one or more solder bumps of the further connecting structure.

12. Semiconductor package according to claim 11, wherein the at least one driver circuit is electrically connected to the connection structure of the package substrate in each case via one or more solder bumps of the further connecting structure via the at least one interposer.

13. Semiconductor package according to claim 1, wherein at least one interposer is at least one semiconductor component.

14. Semiconductor package according to claim 1, wherein a horizontal surface of the at least one interposer projects at least partially laterally beyond a horizontal surface of the surface-emitting laser and the at least one driver circuit.

15. LIDAR transmitting unit comprising a semiconductor package, said semiconductor package comprising:
a surface-emitting laser;
at least one driver circuit for the surface-emitting laser;
a connecting structure, wherein the connecting structure comprises a plurality of solder bumps; and
at least one interposer, wherein the surface-emitting laser is electrically connected to the at least one driver circuit via the at least one interposer and the connecting structure.
